(19) United States
(12) Patent Application Publication
(10) Pub. No.: US 2003/0183367 A1
(43) Pub. Date: Oct. 2, 2003

(54) 10SI alternator housing to accommodate larger improved heavy duty 17SI rectifier

(76) Inventor: Roy N. Karam, Saskatoon (CA)

Correspondence Address: ROY N KARAM, 506 QUANCE AVE., SASKATOON, SK, S7H-3B4, CA

(21) Appl. No.: 10/107,737

(22) Filed: Mar. 28, 2002

(51) Int. Cl. F28F 7/00; H05K 7/20

(52) U.S. Cl. 165/80.3; 165/185; 361/704

(57) ABSTRACT

High output popular small frame alternators have a high rate of failure due to higher heat temperatures typically caused by; 1) continuous higher rate charging, 2) lack of heat dissipation through rectifier heat sinks and diodes, 3) insufficient cooling (air exchange/air flow) through alternator and components, 4) the “plugging” up of alternator by foreign matter such as chaff, dust etc . . . as is common in agricultural, mining and industrial applications and therefore limiting cooling and causing “burn out”.

The invention consists of an improved alternator CE housing to allow for a larger and improved rectifier with larger heat sinks (and thus its exposed surface area) and 950 amp diodes vs. the original 625 amp diodes (and thus increasing its current carrying capability) as well as an improved more open design in the housing and rectifier to allow for more air flow and a cooler running, more durable alternator.

### CROSS-REFERENCE TO RELATED APPLICATIONS

Not-Applicable

### STATEMENT REGARDING FEDERALLY SPONSORED RESEARCH OR DEVELOPMENT

Not-Applicable

### REFERENCE TO A MICROFICHE APPENDIX

Not-Applicable

### BACKGROUND OF THE INVENTION

High output popular small frame alternators on vehicles and machinery used in, automotive, industrial, agricultural and marine industries have a high rate of failure due to higher heat temperatures typically caused by; 1) continuous higher rate charging, 2) lack of heat dissipation through rectifier heat sinks and diodes,3) insufficient cooling (air exchange/air flow) through alternator and components,4) the “plugging up” of alternator by foreign matter such as chaff, dust etc . . . as is common in agricultural, mining and industrial applications and therefore limiting cooling and causing “burn out”.

### BRIEF SUMMARY OF THE INVENTION

Briefly, the invention consists of an improved alternator CE housing to allow for a larger rectifier with larger heat sinks (and thus its exposed surface area) and 950 amp diodes vs. the original 625 amp diodes (and thus increasing its current carrying capability) as well as an improved more open design in the housing and rectifier to allow for more air flow and a cooler running, more durable alternator.

### BRIEF DESCRIPTION OF THE SEVERAL VIEWS OF THE DRAWING

FIG. 1: Depicts the front and back view of the old original rectifier to be replaced.

FIG. 2: Depicts the front and back view of the larger improved heavy duty rectifier.

FIG. 3: Depicts the inside view of the redesigned housing to accommodate the rectifier in FIG. 2.

FIG. 4: Depicts the back view of the redesigned housing to allow for the larger improved rectifier.

FIG. 5: Depicts the inside view of the housing as a sub-assembly with the new rectifier in FIG. 2 installed.

FIG. 6: Depicts the back view of the housing with a larger opening for better ventilation along with the new larger rectifier installed.

### DETAILED DESCRIPTION OF THE INVENTION

This invention relates to an improved alternator housing to allow for the installation of a larger enhanced, heavy duty rectifier and for better cooling and reliability.

It is common in high output small frame alternators to have a high rate of failure due to hotter temperatures developed in small frame alternators caused by, increased continuous high output charging capability, lack of heat dissipation through undersized rectifier heat sinks and diodes, insufficient cooling (air exchange/air flow) through alternator and components, and the plugging up of alternator by foreign matter such as chaff & dust, further limiting the cooling capabilities of the alternator.

We have found that the above factors contributing to early alternator failure can be overcome or significantly reduced. By redesigning the housing to allow for a larger rectifier with larger heat sinks (and thus its exposed surface area) and 950 amp diodes versus the original 625 amp diodes (and thus increasing its current carrying capability) as well as an improved more open design in the housing and rectifier to allow for more air flow and a cooler running, more durable alternator.

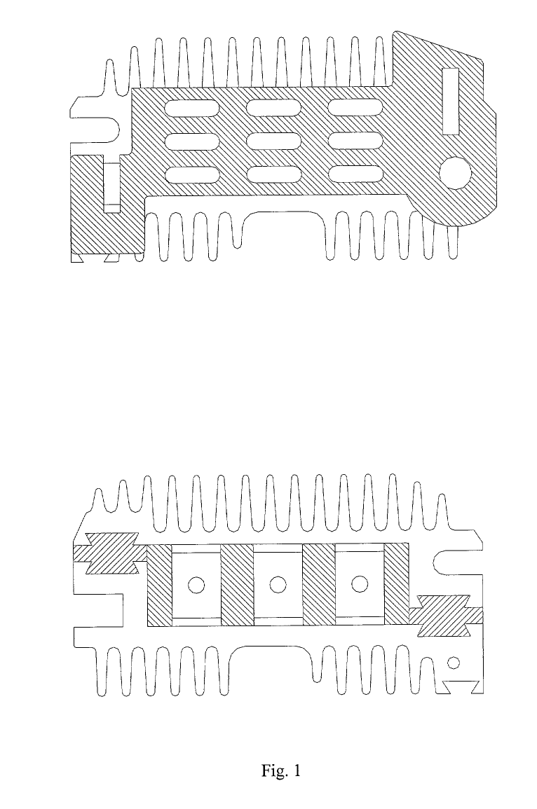

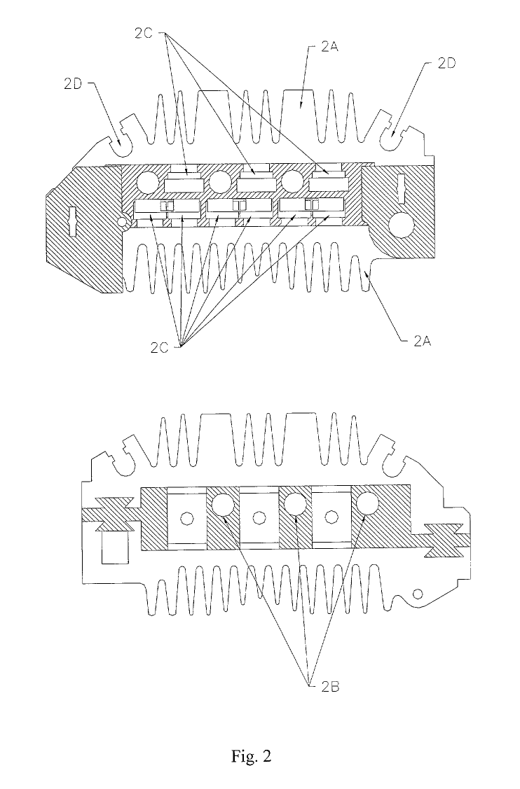

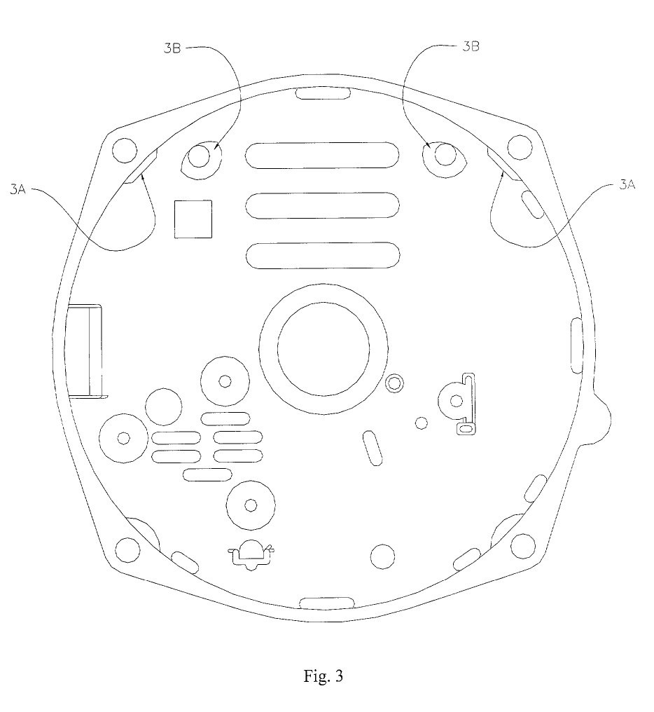

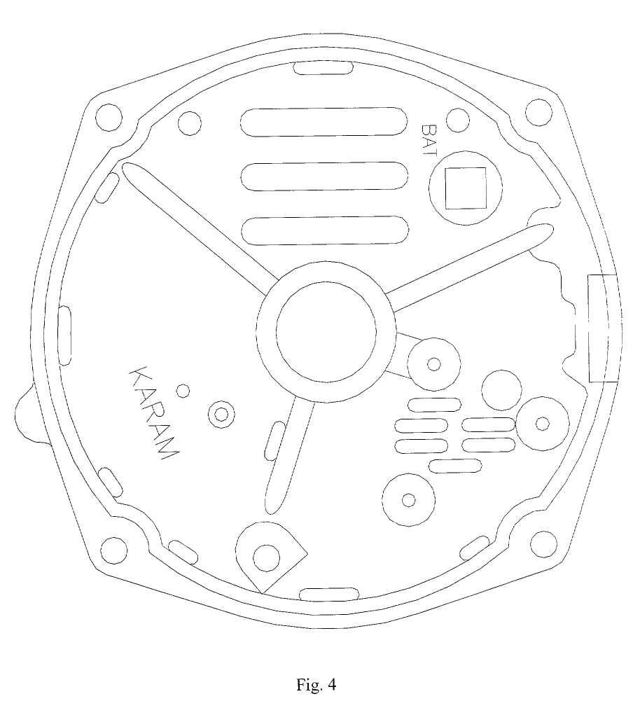

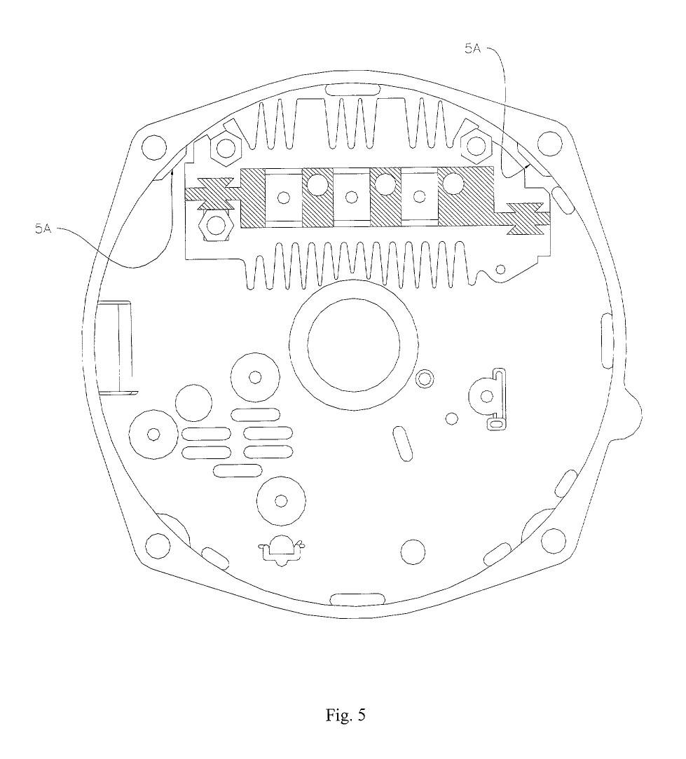

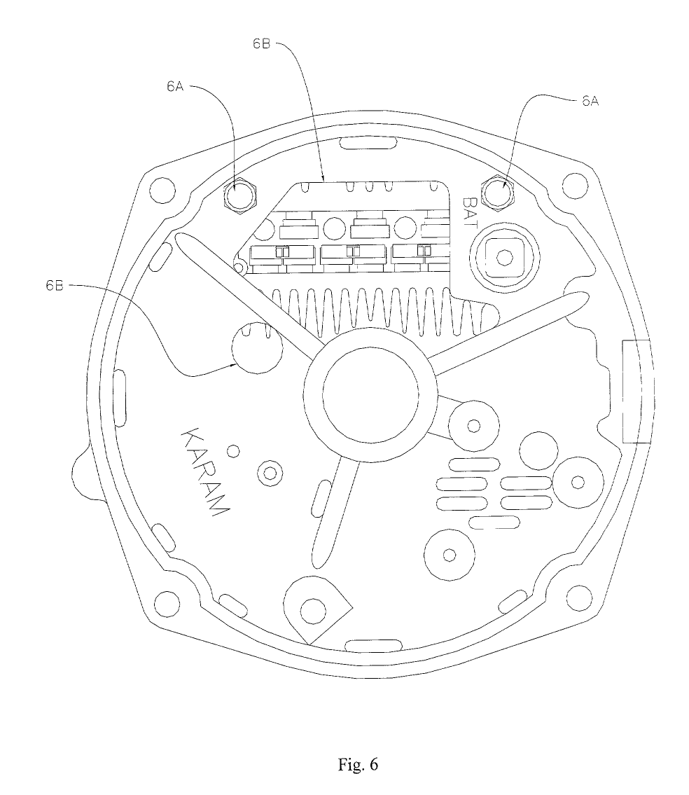

In pictures which illustrate the embodiments of the invention, FIG. 1 is the front and back view of the old original rectifier, FIG. 2 is the front and back view of the larger improved heavy duty rectifier, FIG. 3 is the inside view of the redesigned housing and FIG. 4 is the back view of the redesigned housing to allow for the larger improved rectifier, FIG. 5 is the inside view of the housing with the new rectifier installed and FIG. 6 is the back view of the housing with the rectifier installed as an alternator sub assembly.

The rectifiers illustrated, FIG. 1 the original rectifier, and FIG. 2 the larger improved rectifier clearly show the larger heat sinks (2A) as well as 3 new air flow paths (2B) for better cooling. In addition the new rectifier has 950 Amp diodes (2C) (6 positive & 3 negative diodes), versus the original 625 Amp diodes (3 positive & 3 negative diodes), for increased current handling capability. A cooler diode/rectifier assembly results in significantly increased durability.

The sub-assembly pictured, FIG. 5 illustrates the new improved rectifier installed in the new housing.

Note notches (5A) in the housing to allow clearance for the larger rectifier. The sub-assembly pictured, FIG. 6 illustrates the new housing from the back view with the new heavy duty rectifier. Note the location of the thru bolts (6A) to fasten the new rectifier. Also note the added openings (6B) in the housing for extra ventilation.

The embodiments of the invention in which an exclusive property or privilege is claimed are defined as follows:

1. The claim, an improved “10SI” alternator housing (FIGS. 3 & 4) designed to be used in conjunction with a larger heavy duty improved “17SI” rectifier (FIG. 2) so that the resulting sub-assembly is pictured in FIGS. 5 and 6.

2. In reference to claim 1, the housing in FIGS. 3 and 4.

3. In reference to claims 1 and 2, the small notches (3A) in the housing FIG. 3 allow for added clearance for the larger rectifier heat sink (2A) in FIG. 2.

4. In reference to claims 1 and 2, the extrusions (3B) in the housing FIG. 3 allow for the proper grounding of the larger rectifier negative heat sink (2D) in FIG. 2.

5. In reference to claim 1, the rectifier pictured in FIG. 2.

6. In reference to claims 1 and 5, the increased number of diodes to 9 (2C) in the rectifier FIG. 2 into the “10SI” style housing in FIG. 3.

7. In reference to claims 1 and 5, the air flow paths (2B) in FIG. 2 of the “17SI” style rectifier.

8. In reference to claims 1 and 2, the increased openings in the housing (6B) in FIG. 6 for added air flow.

9. In reference to claim 1, the housing pictured from the inside and back view in various stages as evident in FIG. 3, FIG. 4, FIG. 5 and FIG. 6.
